(19) United States
(12) Patent Application Publication
(10) Pub. No.: US 2024/0135056 A1
(43) Pub. Date: Apr. 25, 2024

(54) DEVICE AND METHOD FOR EVALUATING PERFORMANCE OF WEARABLE MUSCLE ENHANCEMENT DEVICE

(71) Applicant: Electronics and Telecommunications Research Institute, Daejeon (KR)

(72) Inventors: HyunSuk KIM, Daejeon (KR); Woojin KIM, Daejeon (KR); Daewoong CHOI, Daejeon (KR); Oh Cheon KWON, Daejeon (KR); Daesub YOON, Daejeon (KR); Seung-Jun LEE, Daejeon (KR); Hyunwoo JOE, Daejeon (KR)

(73) Assignee: Electronics and Telecommunications Research Institute, Daejeon (KR)

(21) Appl. No.: 18/356,073

(22) Filed: Jul. 19, 2023

(30) Foreign Application Priority Data
Oct. 18, 2022 (KR) 10-2022-0135261
Dec. 27, 2022 (KR) 10-2022-0186123

(51) Int. Cl. G06F 30/20; G06F 30/17

(52) U.S. Cl. CPC G06F 30/20; G06F 30/17

(57) ABSTRACT

Provided are a device and method for evaluating performance of a wearable muscle enhancement device. The method performed by an evaluation system includes receiving feature information of a person and feature information of a wearable muscle enhancement device, generating complex human digital twin information based on the feature information of the person, generating complex device digital twin information based on the feature information of the wearable muscle enhancement device, creating a virtual human wearing a virtual wearable muscle enhancement device based on the complex human (physical/cognitive) digital twin information and the complex device digital twin information, causing the virtual human to perform a predefined motion, calculating a state variable of the virtual human based on a result of performing the motion, and calculating wearability, usability, and interactivity of the wearable muscle enhancement device based on the state variable to evaluate performance of the wearable muscle enhancement device.

### CROSS-REFERENCE TO RELATED APPLICATION

This application claims priority to and the benefit of Korean Patent Application No. 10-2022-0135261, filed on Oct. 19, 2022 and Korean Patent Application No. 10-2022-0186123, filed on Dec. 27, 2022, in Korean Intellectual Property Office, the disclosure of which is incorporated herein by reference in its entirety.

### BACKGROUND

### 1. Field

The present disclosure relates to a system and method for evaluating performance of a wearable muscle enhancement device.

### 2. Discussion of Related Art

A wearable muscle enhancement device is a device that assists a person with his or her muscular strength. The wearable muscle enhancement device can help a person generate greater force than human strength. A wearable muscle enhancement technology may be used in the military field, the industrial field, rehabilitation, training, etc.

Wearable muscle enhancement devices according to related art have problems of heavy weight, a limited degree of freedom, limited wearability, low operational stability, etc. To overcome these drawbacks, various forms of wearable muscle enhancement devices are being developed lately.

Evaluating the performance of a wearable muscle enhancement device according to the related art mainly depends on evaluations by wearers. Accordingly, there is a significant problem in time and cost consumption. Also, when wearers are an elderly and a person with a disability, it is difficult to evaluate the performance of a wearable muscle enhancement device. This is because evaluation is possible only when the elderly and the person with the disability wear the wearable muscle enhancement device.

### SUMMARY

The present disclosure is directed to providing a system and method for simulating a wearable muscle enhancement device in advance using a digital twin.

According to an aspect of the present disclosure, there is provided a method of evaluating performance of a wearable muscle enhancement device, the method including receiving, by an evaluation system, feature information of a person and feature information of a wearable muscle enhancement device, generating, by the evaluation system, complex human digital twin information on the basis of the feature information of the person, generating, by the evaluation system, complex device digital twin information on the basis of the feature information of the wearable muscle enhancement device, creating, by the evaluation system, a virtual human wearing a virtual wearable muscle enhancement device on the basis of the complex human (physical/cognitive) digital twin information and the complex device digital twin information, causing, by the evaluation system, the virtual human to perform a predefined motion, calculating, by the evaluation system, a state variable of the virtual human on the basis of a result of performing the predefined motion, and calculating, by the evaluation system, wearability, usability, and interactivity of the wearable muscle enhancement device on the basis of the state variable to evaluate performance of the wearable muscle enhancement device.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a flowchart illustrating an overall process of evaluating performance of a wearable muscle enhancement device;

FIG. 2 is a flowchart illustrating a process of generating complex human (physical/cognitive) digital twin information and complex device digital twin information;

FIG. 3 is a flowchart illustrating a process of evaluating interactivity, wearability, and usability between a human (physical/cognitive) digital twin and a device digital twin; and

FIG. 4 is a block diagram of a system for evaluating a wearable muscle enhancement device.

### DETAILED DESCRIPTION OF EXEMPLARY EMBODIMENTS

The technology described below may be variously modified and have several embodiments. In the drawings of the specification, specific embodiments of the technology described below may be illustrated. However, the specific embodiments are for the purpose of describing the technology and not for limiting the technology described below thereto. Therefore, it is to be understood that all alterations, equivalents, or substitutes included in technical spirit and technical scope described below are included in the technology described below.

To describe various components, the terms first, second, A, B, etc. may be used. However, the terms are used only for the purpose of distinguishing one component from another and are not intended to limit the components. For example, within the scope of the technology described below, a first component in an embodiment may be named a second component, and likewise, a second component may be named a first component. The term “and/or” includes any and all combinations of a plurality of associated listed items.

Among terms used herein, the singular form includes the plural form unless the context clearly indicates otherwise. The terms “comprise” and the like denote the presence of stated features, numbers, steps, operations, components, parts, or combinations thereof and do not preclude the presence or addition of one or more other features, numbers, steps, operations, components, parts, or combinations thereof.

Before detailed description of the drawings, it is to be noted that components are only classified according to the main function of each component. In other words, two or more components to be described below may be integrated into one component, or one component may be divided into two or more units according to subdivided functions. Each of components to be described below may additionally perform some or all of the functions of other components in addition to the main function thereof, and some of the main functions of components may be exclusively performed by other components.

In the case of performing a method or operation method, a process of the method may be performed in a different order from a stated order unless a specific order is clearly described in context. In other words, the process may be performed in the same order as specified, performed substantially concurrently, or performed in the reverse order.

Hereinafter, an overall process 10 in which a system for evaluating a wearable muscle enhancement device (hereinafter “evaluation system”) evaluates the performance of a wearable muscle enhancement device will be described.

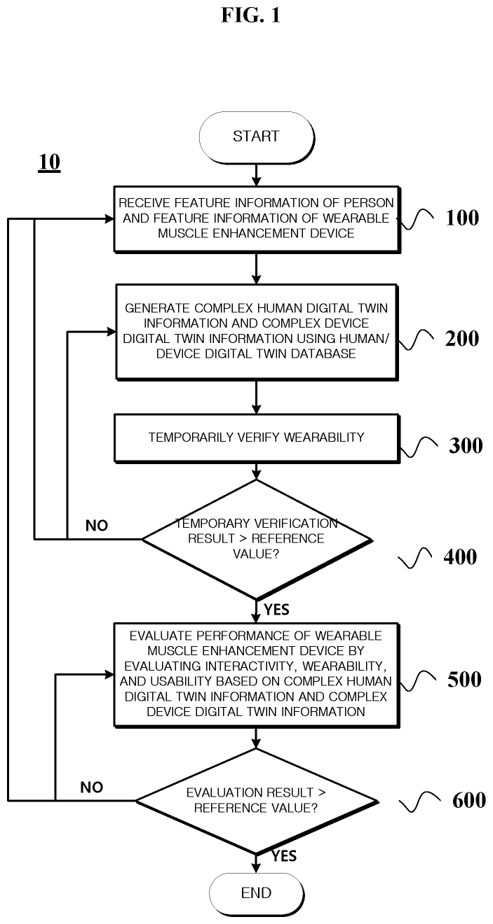

FIG. 1 is a flowchart illustrating an overall process of evaluating performance of a wearable muscle enhancement device.

The evaluation system may receive feature information of a person who will wear a wearable muscle enhancement device and feature information of the wearable muscle enhancement device (100).

The evaluation system may load human (physical/cognitive) and device digital twin information from human (physical/cognitive) and device twin databases (DBs) on the basis of the feature information of the person and the feature information of the wearable muscle enhancement device (200). In this way, the evaluation system may generate complex human (physical/cognitive) digital twin information and complex device digital twin information (200).

The evaluation system may temporarily verify wearability on the basis of the complex human (physical/cognitive) digital twin information and the complex device digital twin information (300).

When the temporary verification result is lower than a preset reference value, the evaluation system may newly receive feature information of a person and feature information of the wearable muscle enhancement device (400). Alternatively, when the temporary verification result is lower than the preset reference value, the evaluation system may newly generate complex human (physical/cognitive) digital twin information and complex device digital twin information (400).

The evaluation system may evaluate the performance of the wearable muscle enhancement device by evaluating interactivity, wearability, and usability between the person and the device on the basis of the complex human (physical/cognitive) digital twin information and the complex device digital twin information (500). In other words, the evaluation system may evaluate the performance of the wearable muscle enhancement device by calculating a performance score of the wearable muscle enhancement device on the basis of interactivity, wearability, and usability.

When the evaluation result is lower than a preset reference value, the evaluation system may newly receive feature information of a person and feature information of the wearable muscle enhancement device (600). Alternatively, when the evaluation result is lower than the preset reference value, the evaluation system may modify functional logic information to perform the evaluation again (600).

When the evaluation result is the preset reference value or more, the evaluation system may propose to a wearable muscle enhancement device designer that a prototype be manufactured according to the features of the wearable muscle enhancement device (not shown).

A process of evaluating performance of a wearable muscle enhancement device will be described in detail below.

First, a process of receiving feature information of a person and feature information of a wearable muscle enhancement device (100 of FIG. 1) will be described.

The feature information of the person may include physical features of the person.

For example, features of the person may include a sex, a size of each body joint, a length of each body joint, and a thickness (or perimeter) of each body joint.

The feature information of the wearable muscle enhancement device may include information on physical features of the wearable muscle enhancement device.

For example, the feature information of the wearable muscle enhancement device may include a size of the wearable muscle enhancement device, a weight of the wearable muscle enhancement device, and a wearing position of the wearable muscle enhancement device.

A process of generating complex human (physical/cognitive) digital twin information and complex device digital twin information (200 of FIG. 1) will be described below.

Complex human (physical/cognitive) digital twin information may include a human (physical/cognitive) digital twin model. The human (physical/cognitive) digital twin model may be a virtual object corresponding to the input features of the person. The complex human (physical/cognitive) digital twin information may include information required for evaluating performance of the wearable muscle enhancement device.

The complex device digital twin information may include a device digital twin model. The device digital twin model may be a virtual object corresponding to the input features of the wearable muscle enhancement device. The complex device digital twin information may include information required for evaluating performance of the wearable muscle enhancement device.

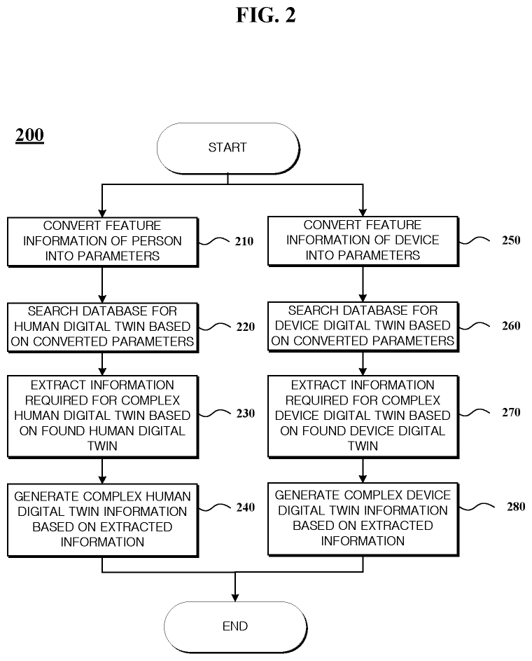

FIG. 2 is a flowchart illustrating a process 200 of generating complex human (physical/cognitive) digital twin information and complex device digital twin information.

First, a process of generating complex human (physical/cognitive) digital twin information will be described (210 to 240).

The evaluation system may convert the received feature information of the person into parameters (210).

The evaluation system may search the human (physical/cognitive) digital twin DB for a human (physical/cognitive) digital twin on the basis of the converted parameters (220).

The evaluation system may extract information required for a complex human (physical/cognitive) digital twin from a found human (physical/cognitive) digital twin (230).

According to an exemplary embodiment, the evaluation system may extract statics data of a basic musculoskeletal model, data such as the nature, magnitude, etc. of dynamic force of the musculoskeletal model, length information of each body joint (anatomical landmarks), myofunctional performance, three-dimensional (3D) model information of the human body, a cognitive processing ability, etc.

The evaluation system may generate complex human (physical/cognitive) digital twin information on the basis of the extracted information (240).

A process of generating complex device digital twin information will be described below (250 to 280).

The evaluation system may convert the received device feature information into parameters (250).

The evaluation system may search the device digital twin DB for a device digital twin on the basis of the converted parameters (260).

The evaluation system may extract information required for a complex device digital twin from a found complex device digital twin (270). According to an exemplary embodiment, the evaluation system may extract device size data, wearing data, data of a sensor included in the device, actuator data, and a function of processing device control logic information.

The evaluation system may generate complex device digital twin information on the basis of the extracted information (280).

A process of temporarily verifying wearability (300 of FIG. 1) will be described below.

The process of temporarily verifying wearability may be a process of temporarily verifying whether wearing the device digital twin causes the human (physical/cognitive) digital twin discomfort.

According to an exemplary embodiment, the evaluation system may compare the size of the human (physical/cognitive) digital twin with the size of the device digital twin. When the sizes of the two digital twins are significantly different, the evaluation system may evaluate that wearing the device digital twin causes the human (physical/cognitive) digital twin discomfort.

When there is a problem in earlier wearability, the evaluation system may receive human feature information and device feature information again. Alternatively, when there is a problem in earlier wearability, the evaluation system may search the human (physical/cognitive) and device digital twin DBs for human (physical/cognitive) and device digital twins again.

A process of evaluating interactivity, wearability, and usability between a human (physical/cognitive) digital twin and a device digital twin (500 of FIG. 1) will be described below.

The evaluation system may evaluate wearability, interactivity, and usability on the basis of the complex human (physical/cognitive) digital twin information and the complex device digital twin information.

According to an exemplary embodiment, the evaluation system may cause the human (physical/cognitive) digital twin and the device digital twin to perform a predefined motion in a simulation. The evaluation system may evaluate interactivity, wearability, and usability by verifying and analyzing implemented functions.

Interactivity may include kinetic benefits from using the wearable muscle enhancement device. Wearability may include the sense of stability obtained from wearing and using the wearable muscle enhancement device. Usability may include the degree of utilizing the wearable muscle enhancement device.

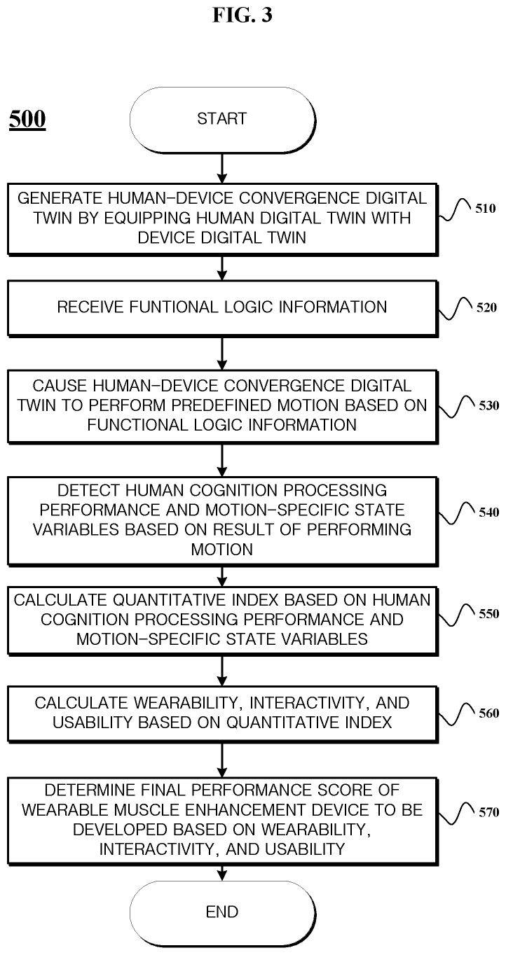

FIG. 3 shows the process 500 in detail in which the evaluation system evaluates wearability, interactivity, and usability between a human (physical/cognitive) digital twin and a device digital twin.

The evaluation system may generate a human-device convergence digital twin on the basis of the complex human (physical/cognitive) digital twin information and the complex device digital twin information (510). The human-device convergence digital twin may be a virtual human wearing a virtual wearable muscle enhancement device.

The evaluation system may receive functional logic information so that the human-device convergence digital twin may perform a predefined motion (520). The functional logic information may be information required for the human-device convergence digital twin to perform predefined motions.

The evaluation system may cause the human-device convergence digital twin to perform the predefined motions on the basis of the functional logic information (530). In other words, the evaluation system may cause the human-device convergence digital twin to perform the predefined motions in a simulation.

The evaluation system may calculate performance of a computational cognition processing function which notifies a user how much cognitive processing is delayed in terms of usability between a human and a device when the user uses the wearable muscle enhancement device, on the basis of results of the predefined motions (540). Alternatively, the evaluation system may detect motion-specific state variables on the basis of the results of the predefined motions (540). The motion-specific state variables may include information such as a joint angle, force applied to a point of application, a torque applied to the point of application, an electromyogram at the point of application, etc.

The evaluation system may calculate a quantitative index on the basis of human cognition processing ability and the motion-specific state variables (550).

The evaluation system may calculate interactivity (kinetic benefits from using the wearable muscle enhancement device), wearability (the sense of stability obtained from wearing/using the wearable muscle enhancement device), usability (the degree of utilizing the wearable muscle enhancement device), etc. on the basis of the quantitative index (560).

The evaluation system may determine a final performance score of the wearable muscle enhancement device to be developed on the basis of the calculated interactivity, wearability, and usability (570).

A configuration of a system for evaluating a wearable muscle enhancement device will be described below.

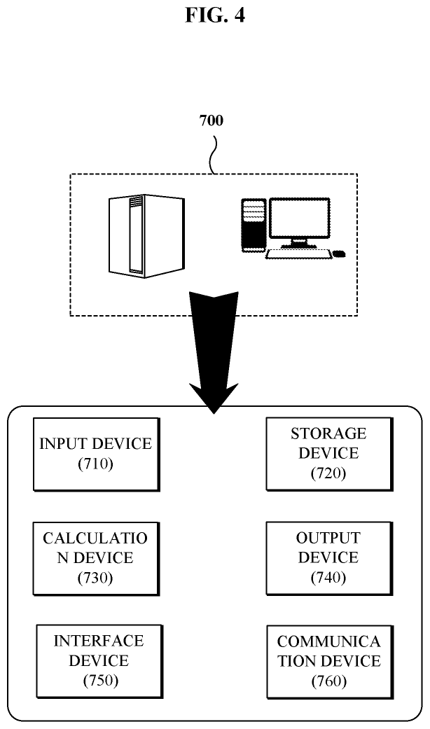

FIG. 4 illustrates a configuration of a system for evaluating a wearable muscle enhancement device.

A system 700 for evaluating a wearable muscle enhancement device may be physically implemented in various forms such as a personal computer (PC), a laptop PC, a smart device, a server, a data processing chipset, etc.

The system 700 for evaluating a wearable muscle enhancement device may include an input device 710, a storage device 720, a calculation device 730, an output device, an interface device 750, and a communication device 760.

The input device 710 may include an interface (a keyboard, a mouse, a touchscreen, etc.) for receiving certain commands or data. The input device 710 may include a component for receiving information through a separate storage device (a universal serial bus (USB) memory, a compact disc (CD), a hard disk, etc.). The input device 710 may receive data through a separate measurement device or a separate DB. The input device 710 may receive data through wired or wireless communication. The input device 710 may receive feature information of a person. The input device 710 may receive feature information of a wearable muscle enhancement device.

The storage device 720 may store the information received through the input device 710. The storage device 720 may store information generated from a calculation process of the calculation device 730. In other words, the storage device 720 may include a memory. The storage device 720 may store a calculation result of the calculation device 730. The storage device 720 may store a human (physical/cognitive) digital twin. The storage device 720 may store a device digital twin. The storage device 720 may store the digital twins as a database. The storage device 720 may store information required for calculation by the calculation device 730.

The calculation device 730 may generate complex human (physical/cognitive) digital twin information on the basis of the feature information of the person. The calculation device 730 may generate complex device digital twin information on the basis of the feature information of the wearable muscle enhancement device. The calculation device 730 may evaluate performance of the wearable muscle enhancement device on the basis of the complex human (physical/cognitive) digital twin information and the complex device digital twin information. The calculation device 730 may generate a control signal. The calculation device 730 may perform the method illustrated in FIGS. 1 to 3.

The output device 740 may be a device that outputs certain information. The output device 740 may output an interface required for data processing, the received data, an analysis result, etc. The output device 740 may be physically implemented in various forms such as a display, a device for outputting a document, etc.

The interface device 750 may be a device that externally receives certain commands and data. The interface device 750 may receive feature information of a person or feature information of the wearable muscle enhancement device from a physically connected input device or external storage device. The interface device 750 may receive a control signal for controlling the system 700. The interface device 750 may output an analysis result of the system 700. The communication device 760 may be a component for receiving and transmitting certain information via a wired or wireless network. The communication device 760 may receive a control signal required for controlling the system 700. The communication device 760 may transmit the analysis result of the system 700.

The above-described system and method for evaluating performance of a wearable muscle enhancement device may be implemented as programs (or applications) including a computer-executable algorithm.

The program may be stored and provided in a transitory or non-transitory computer-readable recording medium.

The non-transitory computer-readable recording medium is a medium that stores data semi-permanently and is readable by a device, rather than a medium that stores data for a short time period such as a register, a cache, a memory, etc. Specifically, the foregoing applications or programs may be stored and provided in a non-transitory computer-readable medium such as a CD, a digital versatile disc (DVD), a hard disk, a Blu-ray disc, a USB memory, a read-only memory (ROM), a programmable read-only memory (PROM), an erasable PROM (EPROM), electrically erasable PROM (EEPROM), a flash memory, etc.

The transitory computer-readable medium is one of various random-access memories (RAMs) such as a static RAM (SRAM), a dynamic RAM (DRAM), a synchronous DRAM (SDRAM), a double data rate (DDR) SDRAM, an enhanced SDRAM (ESDRAM), a synclink DRAM (SLDRAM), and a direct Rambus RAM (DRRAM).

With the above-described technology, it is possible to manufacture a wearable muscle enhancement device fit for various people's bodies using a human (physical/cognitive) digital twin and a device digital twin.

With the above-described technology, it is possible to evaluate the performance of a wearable muscle enhancement device before manufacturing a prototype. In this way, it is possible to reduce time and cost of manufacturing a prototype. As a result, a virtuous cycle of the field of wearable muscle enhancement device technologies and a market ecosystem can be created.

The exemplary embodiments and the drawings appended hereto specify only a part of the technical spirit of the above-described technology, and all modified examples and detailed embodiments easily inferred by those of ordinary skill in the art within the technical spirit included in the specification and drawings of the above-described technology fall within the scope of the above-described technology.

What is claimed is:

1. A method of evaluating performance of a wearable muscle enhancement device, the method comprising:
generating, by an evaluation system, complex human digital twin information on the basis of feature information of a person;
generating, by the evaluation system, complex device digital twin information on the basis of feature information of a wearable muscle enhancement device;
creating, by the evaluation system, a virtual human wearing a virtual wearable muscle enhancement device on the basis of the complex human digital twin information and the complex device digital twin information;
performing, by the evaluation system, a simulation in which the virtual human uses the virtual wearable muscle enhancement device and calculating a state variable of the virtual human using the virtual wearable muscle enhancement device; and
evaluating, by the evaluation system, performance of the wearable muscle enhancement device on the basis of the state variable.

2. The method of claim 1, wherein the state variable includes muscles of a musculoskeletal model of the virtual human, a joint angle of the virtual human, a direction of force at a joint of the virtual human, and an electromyogram at the joint of the virtual human.

3. The method of claim 1, wherein the feature information of the person includes at least one of a sex of the person, a size of each body joint of the person, a length of each body joint of the person, a thickness of each body joint of the person, and a perimeter of each body joint of the person.

4. The method of claim 1, wherein the feature information of the wearable muscle enhancement device includes at least one of a size of the wearable muscle enhancement device, a weight of the wearable muscle enhancement device, and a wearing position of the wearable muscle enhancement device.

5. The method of claim 1, wherein the generating of the complex human digital twin information comprises:
converting, by the evaluation system, the feature information of the person into parameters;
searching, by the evaluation system, a human digital twin database for a human digital twin on the basis of the parameters;
extracting, by the evaluation system, information required for a complex human digital twin from a found human digital twin; and
generating, by the evaluation system, the complex human digital twin information on the basis of the extracted information,
wherein the information required for the complex human digital twin includes at least one of statics data of a basic musculoskeletal model, nature and magnitude data of dynamic force of the musculoskeletal model, length information of each body joint (anatomical landmarks), myofunctional performance, three-dimensional (3D) model information of a human body, and a cognitive processing ability.

6. The method of claim 1, wherein the generating of the complex device digital twin information comprises:
converting, by the evaluation system, the feature information of the wearable muscle enhancement device into parameters;
searching, by the evaluation system, a device digital twin database for a device digital twin on the basis of the parameters;
extracting, by the evaluation system, information required for a complex device digital twin from a found device digital twin; and
generating, by the evaluation system, the complex device digital twin information on the basis of the extracted information,
wherein the information required for the complex device digital twin includes at least one of device size data, wearing data, data of a sensor included in the device, actuator data, and a function of processing device control logic information.

7. The method of claim 1, further comprising temporarily verifying, by the evaluation system, whether wearing the virtual wearable muscle enhancement device causes the human digital twin discomfort,
wherein the temporarily verifying of whether wearing the virtual wearable muscle enhancement device causes the human digital twin discomfort comprises comparing a size of the virtual human and a size of the virtual wearable muscle enhancement device to determine whether there is a difference of a reference value or more.

8. The method of claim 7, further comprising, when there is a problem in a result of temporarily verifying whether wearing the virtual wearable muscle enhancement device causes the human digital twin discomfort, receiving feature information of a person and feature information of the wearable muscle enhancement device again.

9. The method of claim 1, wherein the calculating of the state variable comprises:
receiving, by the evaluation system, functional logic information required for the virtual human to perform a predefined motion;
causing, by the evaluation system, the virtual human to perform the predefined motion on the basis of the functional logic information; and
detecting, by the evaluation system, a cognitive processing ability and motion-specific state variables on the basis of a result of performing the predefined motion.

10. The method of claim 9, wherein the evaluating of the performance of the wearable muscle enhancement device comprises evaluating the performance of the wearable muscle enhancement device by calculating wearability, usability, and interactivity of the wearable muscle enhancement device.

11. The method of claim 10, wherein the evaluating of the performance of the wearable muscle enhancement device comprises:
calculating, by the evaluation system, a quantitative index on the basis of the cognitive processing ability and the motion-specific state variables;
calculating, by the evaluation system, the wearability, the usability, and the interactivity on the basis of the quantitative index; and
evaluating, by the evaluation system, the performance of the wearable muscle enhancement device on the basis of the calculated wearability, usability, and interactivity.

12. A device for evaluating performance of a wearable muscle enhancement device, the device comprising:
an input device configured to receive feature information of a person and feature information of a wearable muscle enhancement device; and
a calculation device configured to generate complex human digital twin information on the basis of the feature information of the person, generate complex device digital twin information on the basis of the feature information of the wearable muscle enhancement device, create a virtual human wearing a virtual wearable muscle enhancement device on the basis of the complex human digital twin information and the complex device digital twin information, calculating a state variable of the virtual human using the virtual wearable muscle enhancement device while performing a simulation in which the virtual human uses the virtual wearable muscle enhancement device, and evaluate performance of the wearable muscle enhancement device on the basis of the state variable.

13. The device of claim 12, wherein the state variable includes muscles of a musculoskeletal model of the virtual human, a joint angle of the virtual human, a direction of force at a joint of the virtual human, and an electromyogram at the joint of the virtual human.

14. The device of claim 12, wherein the feature information of the person includes at least one of a sex of the person, a size of each body joint of the person, a length of each body joint of the person, a thickness of each body joint of the person, and a perimeter of each body joint of the person.

15. The device of claim 12, wherein the feature information of the wearable muscle enhancement device includes at least one of a size of the wearable muscle enhancement device, a weight of the wearable muscle enhancement device, and a wearing position of the wearable muscle enhancement device.

16. The device of claim 12, wherein the calculation device converts the feature information of the person into parameters, searches a human digital twin database for a human digital twin on the basis of the parameters, extracts information required for a complex human digital twin from a found human digital twin, and generates the complex human digital twin information on the basis of the extracted information,
wherein the information required for the complex human digital twin includes at least one of statics data of a basic musculoskeletal model, nature and magnitude data of dynamic force of the musculoskeletal model, length information of each body joint (anatomical landmarks), myofunctional performance, three-dimensional (3D) model information of a human body, and a cognitive processing ability.

17. The device of claim 12, wherein the calculation device converts the feature information of the wearable muscle enhancement device into parameters, searches a device digital twin database for a device digital twin on the basis of the parameters, extracts information required for a complex device digital twin from a found device digital twin, and generates the complex device digital twin information on the basis of the extracted information,
wherein the information required for the complex device digital twin includes at least one of device size data, wearing data, data of a sensor included in the device, actuator data, and a function of processing device control logic information.

18. The device of claim 12, wherein the calculation device temporarily verifies whether wearing the virtual wearable muscle enhancement device causes the human digital twin discomfort,
wherein, to temporarily verify whether wearing the virtual wearable muscle enhancement device causes the human digital twin discomfort, the calculation device compares a size of the virtual human and a size of the virtual wearable muscle enhancement device and determines whether there is a difference of a reference value or more.

19. The device of claim 18, wherein, when there is a problem in a result of temporarily verifying whether wearing the virtual wearable muscle enhancement device causes the human digital twin discomfort, the input device receives feature information of a person and feature information of the wearable muscle enhancement device again.

20. The device of claim 12, wherein the input device further receives functional logic information required for the virtual human to perform a predefined motion,
wherein, to calculate the state variable, the calculation device causes the virtual human to perform the predefined motion on the basis of the functional logic information and then detects a cognitive processing ability and motion-specific state variables on the basis of a result of performing the predefined motion.
